(19) United States
(12) Patent Application Publication
(10) Pub. No.: US 2023/0395488 A1
(43) Pub. Date: Dec. 7, 2023

(54) Passive Device Structure

(71) Applicant: Taiwan Semiconductor Manufacturing Company, Ltd., Hsin-Chu (TW)

(72) Inventors: Yao-Te Huang, Hsinchu City (TW); Yung-Shih Cheng, Hsinchu City (TW)

(21) Appl. No.: 17/832,443

(22) Filed: Jun. 3, 2022

(51) Int. Cl. H01L 23/522; H01L 23/532; H01L 21/768

(52) U.S. Cl. CPC H01L 23/5223; H01L 23/5226; H01L 23/53238; H01L 21/76832

(57) ABSTRACT

Back-end-of-line (BEOL) passive device structures and methods of forming the same are provided. In an embodiment, a semiconductor structure includes a first lower contact feature in a first dielectric layer, an etch stop layer on the first dielectric layer, a metal-insulator-metal (MIM) capacitor formed over the etch stop layer, a second dielectric layer over the MIM capacitor, a first contact via extending through both the second dielectric layer and the MIM capacitor and electrically coupled to the first lower contact feature, and a first upper contact feature over and electrically coupled to the first contact via, where a bottom plate of the MIM capacitor is in direct contact with the etch stop layer.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed. In the course of IC evolution, functional density (i.e., the number of interconnected devices per chip area) has generally increased while geometry size (i.e., the smallest component that can be created using a fabrication process) has decreased.

As the geometry size of IC devices decreases, passive devices that require large surface areas are moved to back-end-of-line (BEOL) structures. Metal-Insulator-Metal (MIM) capacitors are among examples of such passive devices. A typical MIM capacitor includes multiple conductor plate layers that are insulated from one another by multiple insulator layers. Although existing MIM capacitors are generally adequate for their intended purposes, they are not satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method for fabricating a device structure, according to various aspects of the present disclosure.

FIGS. 2-14 are fragmentary cross-sectional views of a workpiece during various fabrication stages in the method of FIG. 1, according to various aspects of the present disclosure.

FIG. 15 depicts a fragmentary top view of the workpiece shown in FIG. 14, according to various aspects of the present disclosure.

FIG. 16 is a fragmentary cross-sectional view of an alternative workpiece, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Metal-Insulator-Metal (MIM) capacitors have been widely used in functional circuits such as mixed signal circuits, analog circuits, radio frequency (RF) circuits, dynamic random-access memories (DRAMs), embedded DRAMs, and logic operation circuits. In system-on-chip (SOC) applications, different capacitors for different functional circuits may be integrated on a same chip to serve different purposes. For example, in mixed-signal circuits, capacitors may be used as decoupling capacitors and high-frequency noise filters. For DRAM and embedded DRAM circuits, capacitors may be used for memory storage, while for RF circuits, capacitors may be used in oscillators and phase-shift networks for coupling and/or bypassing purposes. For microprocessors, capacitors may be used for decoupling.

As its name suggests, an MIM capacitor includes a sandwich structure of interleaving metal layers and insulator layers. An example MIM capacitor includes multiple conductor plate layers, each of which is insulated from an adjacent conductor plate layer by an insulator layer. First type of contact vias may be formed to electrically couple to the conductor plate layers of the MIM capacitor, second type of contact vias may be formed to electrically couple to contact features disposed under the MIM capacitor. The conductor plate layers and the contact features may have different compositions and thus an etchant may etch the conductor plate layers and the contact features at different etch rates. In some existing technologies, to form of those contact vias, some embodiments may need to form an etch stop layer on each conductor plate layer of the MIM capacitor to facilitate the formation of those contact vias.

The present disclosure provides a method to simplify the formation of an MIM capacitor and the contact vias. In an embodiment, a device structure includes a lower contact feature in a first dielectric layer, an etch stop layer on the first dielectric layer, a metal-insulator-metal (MIM) capacitor formed over the etch stop layer. A bottom plate of the MIM capacitor is in direct contact with the etch stop layer. The device structure also includes a second dielectric layer over the MIM capacitor, a contact via extending through both the second dielectric layer and the MIM capacitor and electrically coupled to the lower contact feature, and an upper contact feature over and electrically coupled to the contact via. Instead of providing an etch stop layer on the conductor plate layer of the MIM capacitor and forming a contact via directly on the conductor plate layer, forming a contact via penetrating the conductor plate layer may be advantageously simplify the fabrication process. In some embodiments, a parasitic capacitance of the device structure may be reduced.

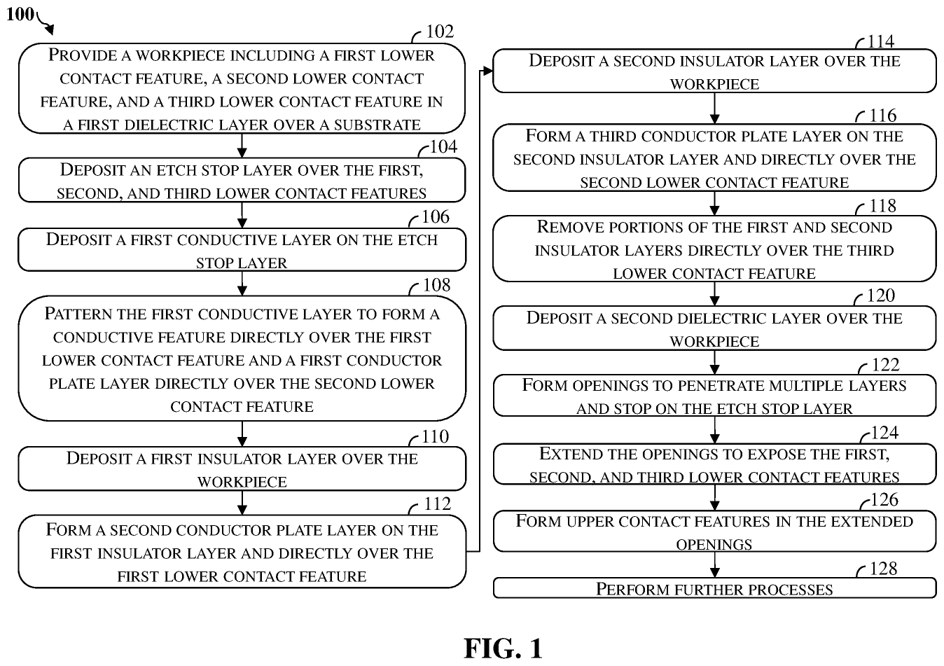

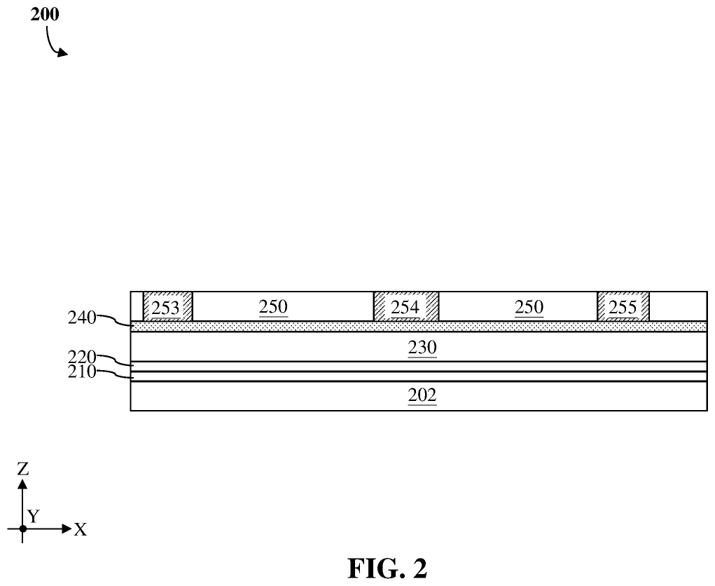

The various aspects of the present disclosure will now be described in more detail with reference to the figures. In that regard, FIG. 1 is a flowchart illustrating a method 100 for fabricating a device structure, according to embodiments of the present disclosure. Method 100 is merely an example and is not intended to limit the present disclosure to what is explicitly illustrated in method 100. Additional steps can be provided before, during, and after method 100, and some steps described can be replaced, eliminated, or moved around for additional embodiments of the method. Not all steps are described herein in detail for reasons of simplicity. Method 100 is described below in conjunction with FIGS. 2-16, which are fragmentary cross-sectional views or top views of a workpiece at different stages of fabrication according to embodiments of method 100. Because the workpiece 200 will be fabricated into a device structure at the conclusion of the fabrication processes, the workpiece 200 may also be referred to as a device structure 200 or a device structure 200′ as the context requires. Additionally, throughout the present application, like reference numerals denote like features, unless otherwise excepted.

Referring to FIGS. 1 and 2, method 100 includes a block 102 where a workpiece 200 is provided. The workpiece 200 includes various layers already formed thereon. The workpiece 200 includes a substrate 202, which may be made of silicon or other semiconductor materials such as germanium. The substrate 202 also may include a compound semiconductor such as silicon carbide, gallium arsenic, indium arsenide, or indium phosphide. In some embodiments, the substrate 202 may include alloy semiconductor such as silicon germanium, silicon germanium carbide, gallium arsenic phosphide, or gallium indium phosphide. In some embodiments, the substrate 202 may include an epitaxial layer, such as an epitaxial layer overlying a bulk semiconductor. Various microelectronic components may be formed in or on the substrate 202, such as transistor components including source/drain features, gate structures, gate spacers, source/drain contacts, gate contacts, isolation structures including shallow trench isolation (STI), or any other suitable components. Source/drain feature(s) may refer to a source or a drain, individually or collectively dependent upon the context. Transistors formed on the substrate 202 may be planar devices or multi-gate devices. Multi-gate devices include, for example, fin-like field effect transistors (FinFETs) or multi-bridge-channel (MBC) transistors. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor.

The workpiece 200 also includes a multi-layered interconnect (MLI) structure 210, which provides interconnections (e.g., wiring) between the various microelectronic components of the workpiece 200. The MLI structure 210 may also be referred to as an interconnect structure 210. The MLI structure 210 may include multiple metal layers or metallization layers. In some instances, the MLI structure 210 may include eight (8) to fourteen (14) metal layers. Each of the metal layers includes multiple conductive components embedded in an intermetal dielectric (IMD) layer. The conductive components may include contacts, vias, or metal lines. The IMD layer may be a silicon oxide or silicon-oxide-containing material where silicon exists in various suitable forms. As an example, the IMD layer includes silicon oxide or a low-k dielectric material having k-value (dielectric constant) smaller than that of silicon oxide, which is about 3.9. In some embodiments, the low-k dielectric material includes a porous organosilicate thin film such as SiOCH, tetraethylorthosilicate (TEOS) oxide, un-doped silicate glass, doped silicon oxide such as borophosphosilicate glass (BPSG), fused silica glass (FSG), phosphosilicate glass (PSG), fluorine-doped silicon dioxide, carbon-doped silicon dioxide, porous silicon dioxide, porous carbon-doped silicon dioxide, silicon carbon nitride (SiCN), silicon oxycarbide (SiOCN), spin-on silicon based polymeric dielectrics, or combinations thereof.

In an embodiment, a carbide layer 220 is deposited on the MLI structure 210. The deposition process includes chemical vapor deposition (CVD), physical vapor deposition (PVD), atomic layer deposition (ALD), or combinations thereof. Any suitable type of carbide material such as silicon carbide (SiC) can be used in the carbide layer 220.

In an embodiment, an oxide layer 230 is deposited on the carbide layer 220. Any suitable deposition process for the oxide layer 230 may be used, including CVD, flowable CVD (FCVD), spin-on coating, PVD, ALD, or combinations thereof. In some embodiments, the oxide layer 230 includes undoped silicon oxide.

In an embodiment, a first etch stop layer (ESL) 240 is deposited on the oxide layer 230. The first ESL 240 may include silicon carbonitride (SiCN), silicon oxycarbide (SiOC), silicon carbide (SiC), silicon oxycarbonitride (SiOCN), or silicon nitride (SiN), or combinations thereof and may be formed by chemical vapor deposition (CVD), physical vapor deposition (PVD), atomic layer deposition (ALD), or combinations thereof.

A first dielectric layer 250 may be deposited on the first ESL 240. A composition of the first dielectric layer 250 may be similar to that of the oxide layer 230. In some embodiments, the first dielectric layer 250 includes undoped silica glass (USG) or silicon oxide. The first dielectric layer 250 may be deposited using CVD, flowable CVD (FCVD), spin-on coating, PVD, ALD, or combinations thereof. In some embodiments, the first dielectric layer 250 may be about 800 nm to about 1000 nm thick.

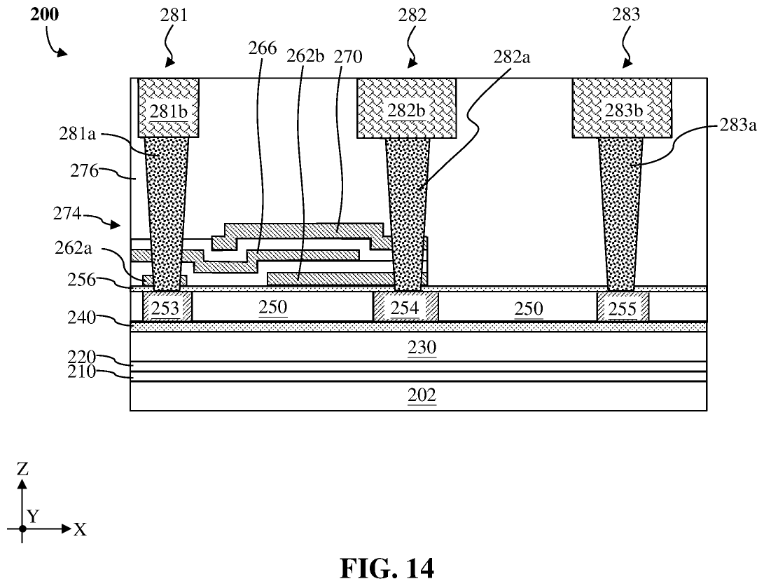

The workpiece 200 also includes a number of lower contact features (e.g., a lower contact feature 253, a lower contact feature 254, and a lower contact feature 255) formed in the first dielectric layer 250. In some embodiments, the lower contact feature 253 may be a dummy contact feature or a functional contact feature, and the lower contact feature 254 may be a dummy contact feature or a functional contact feature, depending on different design requirements. The formation of the lower contact features may include patterning of the first dielectric layer 250 to form trenches and deposition of a barrier layer (not separately labeled) and a metal fill layer (not separately labeled) in the trenches. In some embodiments, the barrier layer may include titanium nitride or tantalum nitride and may be conformally deposited using PVD, CVD, metalorganic CVD (MOCVD), or a suitable method. In one embodiment, the barrier layer may include tantalum nitride. The metal fill layer may include copper (Cu) and may be deposited using electroplating or electroless plating. After the barrier layer and the metal fill layer are deposited, a planarization process, such as a chemical mechanical planarization (CMP) process, may be performed to remove excess barrier layer and metal fill layer to form the lower contact features 253, 254 and 255. Although the lower contact features 253, 254, and 255 are disposed below upper contact features (such as upper contact features 281, 282, 283 shown in FIG. 14), the lower contact features 253, 254, and 255 are sometimes referred to as top metal (TM) contacts.

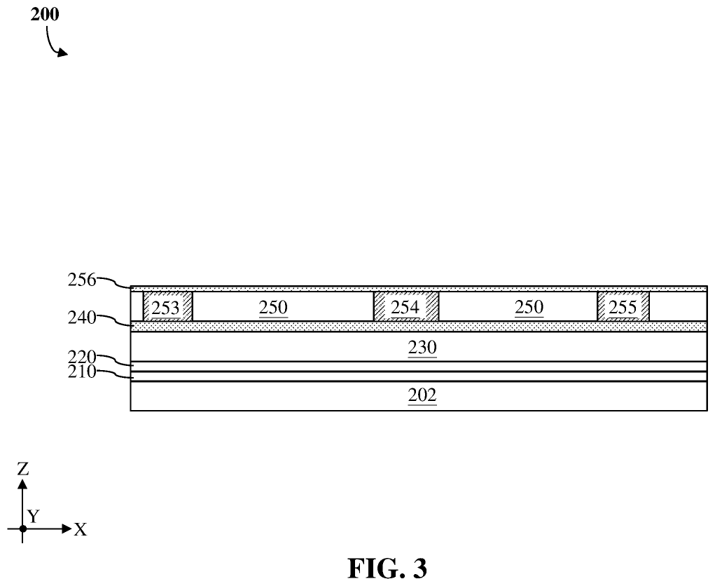

Referring to FIGS. 1 and 3, method 100 includes a block 104 where a second etch stop layer 256 is formed over the workpiece 200. In an embodiment, the second etch stop layer 256 includes silicon carbide (SiC), aluminum nitride, a combination thereof, or other suitable materials that may protect the lower contact features 253, 254, and 255 from being oxidized. The second etch stop layer 256 may be deposited using CVD, PECVD, or a suitable method and may have a thickness between about 110 nm and about 130 nm. In the present embodiments, the second etch stop layer 256 is in direct contact with the top surfaces of the lower contact features 253, 254, and 255.

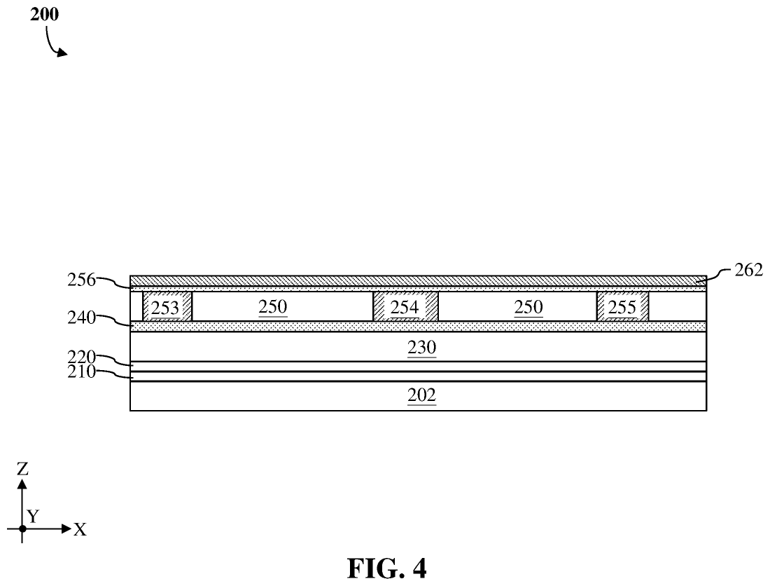

Referring to FIGS. 1 and 4, method 100 includes a block 106 where a first conductive layer 262 is formed directly on the second etch stop layer 256. The first conductive layer 262 may be deposited on the second etch stop layer 256 using PVD, CVD, or MOCVD. In some embodiments, the first conductive layer 262 may include a transition metal or a transition metal nitride. For example, the first conductive layer 262 may include titanium (Ti), tantalum (Ta), titanium nitride (TiN), or tantalum nitride (TaN). In one embodiment, the first conductive layer 262 includes tantalum nitride (TaN). In some alternative embodiments, the first conductive layer 262 may include copper (Cu), cobalt (Co), nickel (Ni), tungsten (W), or aluminum (Al). The deposited first conductive layer 262 may cover an entire top surface of the workpiece 200.

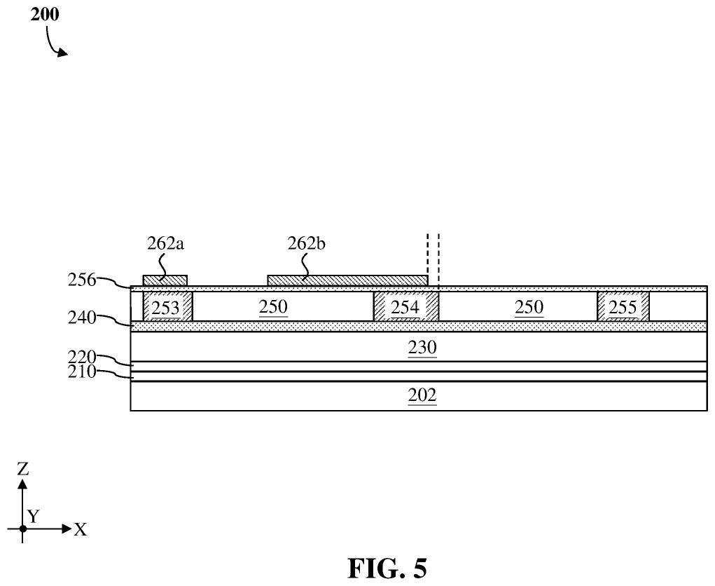

Referring to FIGS. 1 and 5, method 100 includes a block 108 where the first conductive layer 262 is patterned to form a conductive feature 262a directly over the lower contact feature 253 and a conductive feature 262b directly over the lower contact feature 254. The patterning may include deposition of a hard mask layer over the first conductive layer 262, formation of a photoresist layer over the hard mask layer, patterning of the photoresist layer using photolithography, etching of the hard mask layer using the patterned photoresist layer as an etch mask, and then etching of the first conductive layer 262 using the patterned hard mask as an etch mask. Since the conductive feature 262a and the conductive feature 262b are formed by patterning the first conductive layer 262, the conductive feature 262a and the conductive feature 262b are formed simultaneously and are formed of the same composition. In an embodiment, the conductive feature 262b partially vertically overlaps with the lower contact feature 254 and partially vertically overlaps with a portion of the first dielectric layer 250 disposed between the lower contact feature 253 and the lower contact feature 254. For example, as indicated by the dashed lines in FIG. 5, a sidewall surface of the conductive feature 262b is offset from a sidewall surface of the lower contact feature 254. In an embodiment, a width of the conductive feature 262a along the X direction is smaller than a width of the conductive feature 262b along the X direction. In the present embodiments, the conductive feature 262a may be referred to as a dummy plate layer 262a, and the conductive feature 262b may be referred to as a first conductor plate layer 262b of a MIM capacitor structure.

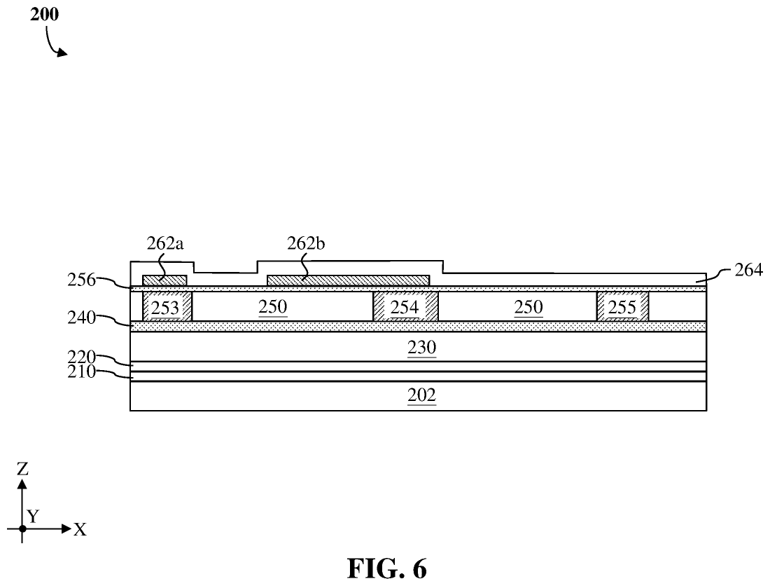

Referring to FIGS. 1 and 6, method 100 includes a block 110 where a first insulator layer 264 is deposited over the workpiece 200. As shown in FIG. 6, after the first conductive layer 262 is patterned to form the dummy plate layer 262a and the first conductor plate layer 262b, a first insulator layer 264 is deposited. In an embodiment, the first insulator layer 264 is conformally deposited to have a generally uniform thickness over the top surface of the workpiece 200 (e.g., having about the same thickness on top and sidewall surfaces of the first conductor plate layer 262b). The first insulator layer 264 may be deposited using CVD, ALD, or a suitable deposition method. The first insulator layer 264 may be a high-k dielectric layer and may include hafnium oxide, aluminum oxide, zirconium oxide, titanium oxide, tantalum oxide, or a combination thereof. The first insulator layer 264 may be a single layer structure or a multi-layer structure. In the present embodiments, the first insulator layer 264 includes a first portion formed directly on the dummy plate layer 262a, a second portion formed directly on the first conductor plate layer 262b, a third portion formed between the dummy plate layer 262a and the first conductor plate layer 262b, and a fourth portion formed directly on the second etch stop layer 256 and directly over the lower contact feature 255.

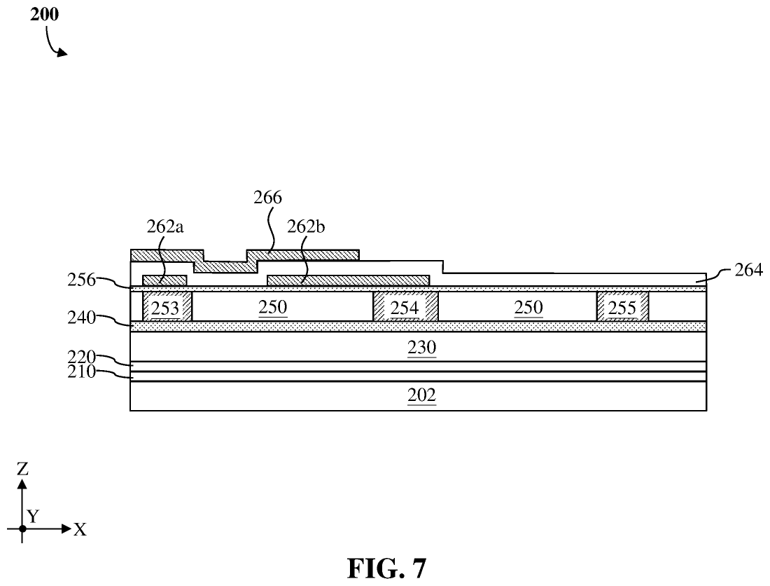

Referring to FIGS. 1 and 7, method 100 includes a block 112 where a second conductor plate layer 266 is formed on the first insulator layer 264. The second conductor plate layer 266 may be formed in a way similar to the formation of the first conductor plate layer 262b. For example, a second conductive layer may be deposited to cover an entire top surface of the workpiece 200 and then patterned to form the second conductor plate layer 266. In some embodiments, the second conductor plate layer 266 may include a transition metal or a transition metal nitride. For example, the second conductor plate layer 266 may include titanium (Ti), tantalum (Ta), titanium nitride (TiN), or tantalum nitride (TaN). In one embodiment, the second conductor plate layer 266 includes tantalum nitride (TaN). In some alternative embodiments, the second conductor plate layer 266 may include copper (Cu), cobalt (Co), nickel (Ni), tungsten (W), or aluminum (Al). In the present embodiments, the second conductor plate layer 266 is vertically overlapped with the first conductor plate layer 262b and is disposed directly over the lower contact feature 253 and the dummy plate layer 262a. Also, there is no vertical overlap between the second conductor plate layer 266 and the lower contact feature 254.

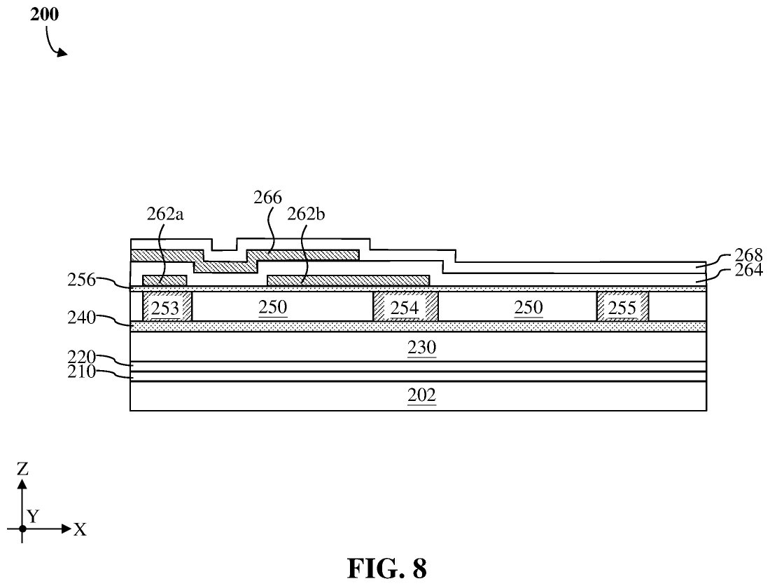

Referring to FIGS. 1 and 8, method 100 includes a block 114 where a second insulator layer 268 is formed over the workpiece 200. In an embodiment, the second insulator layer 268 is conformally deposited to have a generally uniform thickness over the top surface of the workpiece 200 (e.g., having about the same thickness on top and sidewall surfaces of the second conductor plate layer 266). The second insulator layer 268 may be deposited using CVD, ALD, or a suitable deposition method. The second insulator layer 268 may be include hafnium oxide, aluminum oxide, zirconium oxide, titanium oxide, tantalum oxide, or a combination thereof. In the present embodiments, as shown in FIG. 8, the second insulator layer 268 includes a first portion disposed directly on the second conductor plate layer 266, and a second portion disposed directly on the first insulator layer 264. The second portion of the second insulator layer 268 includes a part disposed directly over the lower contact feature 254 and a part disposed directly over the lower contact feature 255.

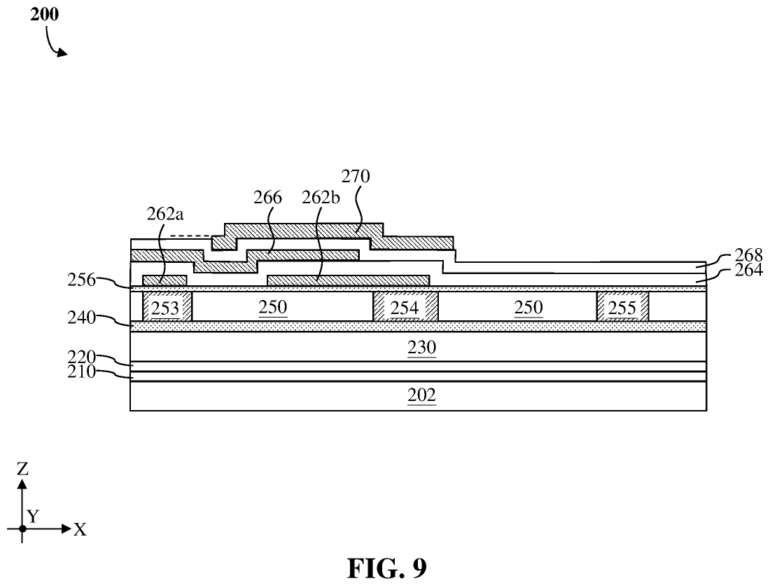

Referring to FIGS. 1 and 9, method 100 includes a block 116 where a third conductor plate layer 270 is formed on the second insulator layer 268. The third conductor plate layer 270 may be formed in a way similar to the formation of the second conductor plate layer 266 or the first conductor plate layer 262b. For example, a third conductive layer may be deposited to cover an entire top surface of the workpiece 200 and then patterned to form the third conductor plate layer 270. In some embodiments, the third conductor plate layer 270 may be deposited over the second insulator layer 268 using PVD, CVD, or MOCVD. In some embodiments, the third conductor plate layer 270 may include a transition metal or a transition metal nitride. For example, the third conductor plate layer 270 may include titanium (Ti), tantalum (Ta), titanium nitride (TiN), or tantalum nitride (TaN). In one embodiment, the third conductor plate layer 270 includes tantalum nitride (TaN). In some alternative embodiments, the third conductor plate layer 270 may include copper (Cu), cobalt (Co), nickel (Ni), tungsten (W), or aluminum (Al). In the present embodiments, the third conductor plate layer 270 is vertically overlapped with both the first conductor plate layer 262b and the second conductor plate layer 266. The third conductor plate layer 270 is disposed directly over the lower contact feature 254 and is not vertically overlapped with the dummy plate layer 262a and the lower contact feature 253. In the embodiment represented in FIG. 9, a lowest portion of a top surface of the third conductor plate layer 270 is above a highest portion of a top surface of the second insulator layer 268, as indicated by the dashed line shown in FIG. 9.

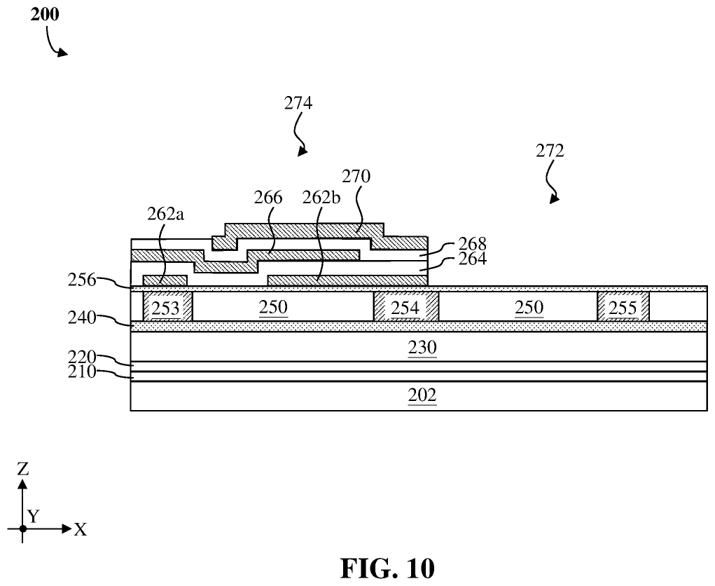

Referring to FIGS. 1 and 10, method 100 includes a block 118 where portions of the first insulator layer 264 and the second insulator layer 268 disposed directly over the lower contact feature 255 are removed. In the present embodiments, after forming the third conductor plate layer 270, while using a patterned mask film (not shown) as an etch mask, an etching process is performed to remove portions of the first insulator layer 264 and the second insulator layer 268 disposed directly over the lower contact feature 255 to form an opening 272. The opening 272 exposes a part of the second etch stop layer 256. In the present embodiments, the patterned mask film exposes a part of the third conductor plate layer 270, and this part of the third conductor plate layer 270 is also removed by the etching process.

After the partially removal of the first insulator layer 264 and the second insulator layer 268, the structure of a MIM capacitor 274 is also finalized. As illustrated in FIG. 10, the MIM capacitor 274 includes multiple conductive layers, including the first conductor plate layer 262b, the second conductor plate layer 266, and the third conductor plate layer 270, which function as plates. The MIM capacitor 274 also includes multiple insulator layers including, the first insulator layer 264 disposed between the first conductor plate layer 262b and the second conductor plate layer 266, as well as the second insulator layer 268 disposed between the second conductor plate layer 266 and the third conductor plate layer 270. The MIM capacitor 274 may be implemented as one or more capacitors, which may be connected to other electric components such as transistors. After the etching process, a sidewall surface of the third conductor plate layer 270 aligns with the sidewall surface of the first conductor plate layer 262b, a sidewall surface of the first insulator layer 264, and a sidewall surface of the second insulator layer 268. In some embodiments, the first insulator layer 264 and the second insulator layer 268 may be formed of high-k dielectric materials. The partially removal of the high-k first insulator layer 264 and the second insulator layer 268 may advantageously reduce a parasitic capacitance (e.g., parasitic capacitance between the contact via portion 282a and the contact via portion 283a) of a final structure of the workpiece 200 in FIG. 14.

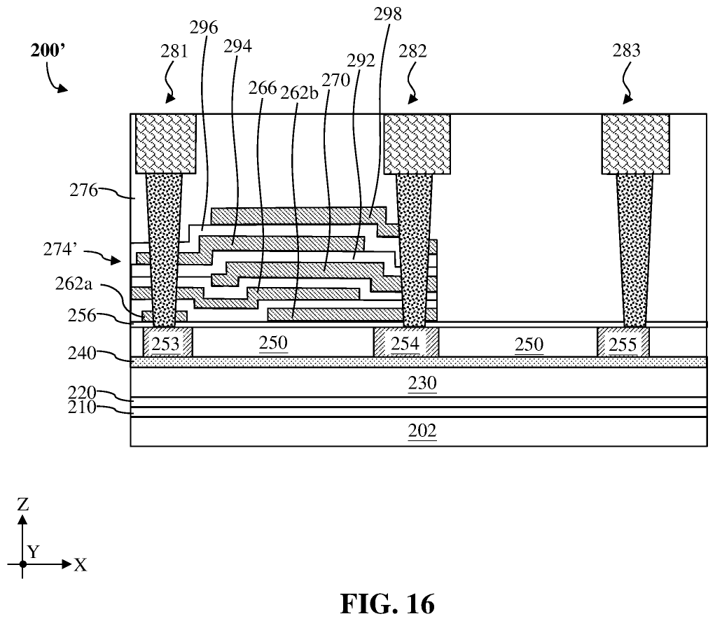

While the MIM capacitor 274 depicted in the present disclosure includes three conductor plate layers, an MIM capacitor according to the present disclosure may include more than 3 conductor plate layers, such as 4, 5, 6, or even more conductor plate layers. Adjacent conductor plate layers are insulated from one another by an insulator layer, similar to the first insulator layer 264 and the second insulator layer 268. FIG. 16 depicts an alternative workpiece 200′ that includes an MIM capacitor 274′ having five conductor plate layers. Detailed description of the workpiece 200′ will be described in further detail with reference to FIG. 16.

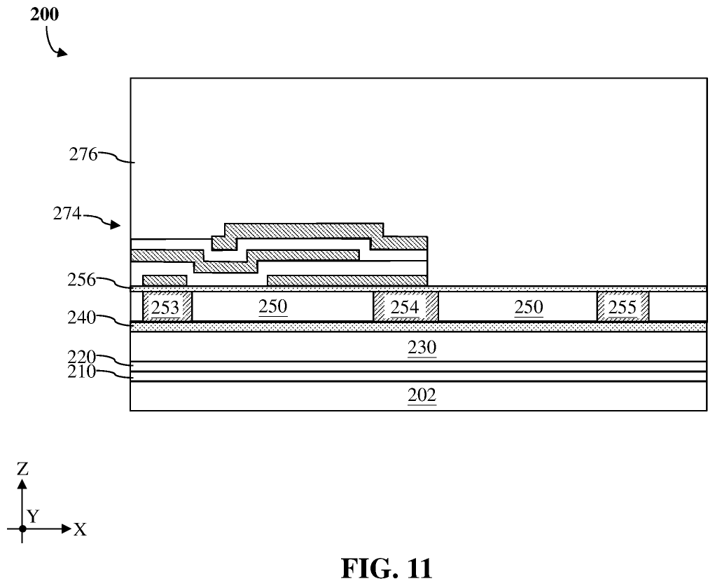

Referring to FIGS. 1 and 11, method 100 includes a block 120 where a second dielectric layer 276 is deposited over the MIM capacitor 274. The composition and formation of the second dielectric layer 276 may be in a way similar to those of the IMD layer in the MLI structure 210. For example, the second dielectric layer 276 may include silicon oxide, silicon-oxide-containing material, or any suitable low-k dielectric materials. As shown in FIG. 11, the MIM capacitor 274 is sandwiched between the second dielectric layer 276 and the second etch stop layer 256. A thickness of the second dielectric layer 276 is greater than a thickness of the second etch stop layer 256. In some embodiments, the second dielectric layer 276 is a single-layer structure. In some other embodiments, the second dielectric layer 276 may be a multi-layer structure. For example, the second dielectric layer 276 includes a first oxide layer formed on a second oxide layer.

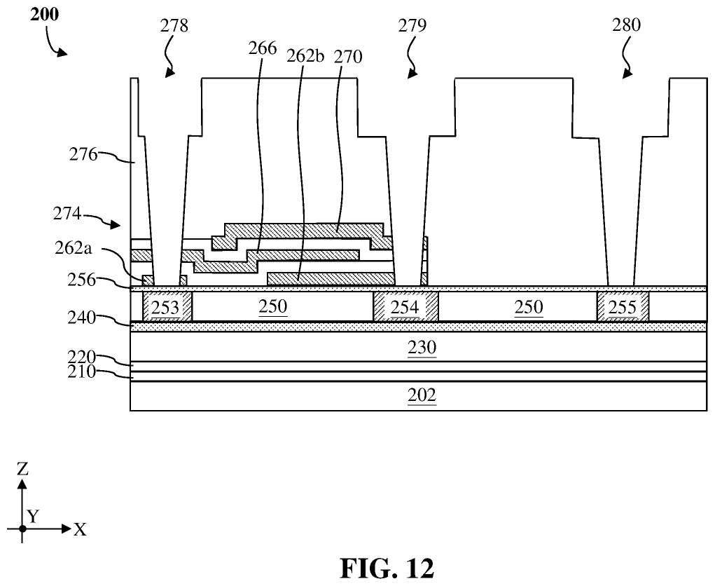

Referring to FIGS. 1 and 12, method 100 includes a block 122 where openings 278, 279, and 280 are formed to penetrate through the second dielectric layer 276 and several layers of the MIM capacitor 274. One or more etching processes may be performed to the workpiece 200 until the etch stop layer 256 is exposed. The one or more etching processes may etch the second dielectric layer 276 and the multiple layers of the MIM capacitor 274 at an etch rate greater than etching the second etch stop layer 256. As shown in FIG. 12, the opening 278 extends through the second insulator layer 268, the second conductor plate layer 266, the first insulator layer 264, and the dummy plate layer 262a. The opening 279 extends through the third conductor plate layer 270, the second insulator layer 268, the first insulator layer 264, and the first conductor plate layer 262b. That is, sidewalls of the second conductor plate layer 266 are exposed in the opening 278 and sidewalls of the first conductor plate layer 262b and the third conductor plate layer 270 are exposed in the opening 279. The opening 280 doesn't extend through any layer of the MIM capacitor 274 and are not in direct contact with the MIM capacitor 274.

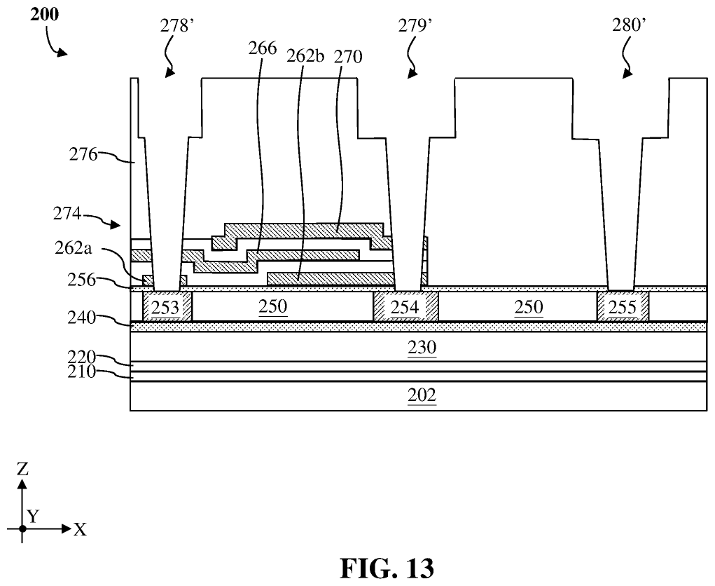

Referring to FIGS. 1 and 13, method 100 includes a block 124 where the openings 278, 279, and 280 are vertically extended to penetrate through the second etch stop layer 256 and expose the lower contact features 253-255. The extended openings 278, 279, and 280 may be referred to as openings 278′, 279′, and 280′. In some embodiments, a wet etching process may be used to selectively etch the second etch stop layer 256 to extend the openings 278, 279, and 280.

Referring to FIGS. 1 and 14, method 100 includes a block 126 where upper contact features 281, 282, and 283 are formed in the openings 278′, 279′, and 280′, respectively. As shown in FIG. 14, each of the upper contact features 281, 282, and 283 includes a contact via portion (e.g., contact via portion 281a, contact via portion 282a, contact via portion 283a) and a metal line portion (e.g., metal line portion 281b, metal line portion 282b, metal line portion 283b) disposed over the contact via portion. Although indicated by different patterns, the contact via portions and the metal line portions may have the same composition. The contact via portions provide vertical electrical connection and the metal line portions extend lengthwise along the Y direction. The upper contact feature 281 includes a contact via portion 281a and a metal line portion 281b. The upper contact feature 282 includes a contact via portion 282a and a metal line portion 282b. The upper contact feature 283 includes a contact via portion 283a and a metal line portion 283b. In some embodiments, the upper contact features 281, 282, and 283 each may include a barrier layer and a metal fill layer over the barrier layer. The barrier layer may include titanium nitride (TiN), tantalum nitride (TaN), or another metal nitride. The metal fill layer may be formed of copper (Cu), aluminum (Al), or an alloy thereof.

The metal line portions 281b, 282b, and 283b may be part of a redistribution layer (RDL) to reroute bond connections between upper and lower layers. The contact via portions 281a, 282a, and 283a each may penetrate through different regions of the MIM capacitor 274 or the second dielectric layer 276. The contact via portion 281a electrically couples to sidewalls of the second conductor plate layer 266 and the dummy plate layer 262a and a top surface of the lower contact feature 253 but is electrically insulated from the first conductor plate layer 262b and the third conductor plate layer 270. The contact via portion 282a electrically couples to the first conductor plate layer 262b, the third conductor plate layer 270 and the lower contact feature 254 but is electrically insulated from the second conductor plate layer 266. The contact via portion 283a may be a logic contact via that is electrically coupled to the lower contact feature 255 but is electrically insulated from the functional portion of the MIM capacitor 274. That is, the contact via portion 283a is electrically insulated from any of the first conductor plate layer 262b, the second conductor plate layer 266, and the third conductor plate layer 270.

During operation of the workpiece 200, a first voltage may be applied to the metal line portion 283b, and a second voltage may be applied to the lower contact feature 255. The second voltage is different from the first voltage such that current will flow between the metal line portion 283b and the lower contact feature 255. That is, both the metal line portion 283b and the lower contact feature 255 are functional conductive features. During operation of the MIM capacitor 274, however, a third voltage may be applied to the metal line portion 281b or the lower contact feature 253 to provide a voltage to the second conductor plate layer 266, a fourth voltage may be applied to the metal line portion 282b or the lower contact feature 254 to provide a voltage to the first conductor plate layer 262b and the third conductor plate layer 270. That is, there is no current between the metal line portion 281b and the lower contact feature 253, and there is no current between the metal line portion 282b and the lower contact feature 254. In some embodiments, the third voltage may be applied to the metal line portion 281b, and the lower contact feature 253 may be referred to as a dummy conductive feature; or the third voltage may be applied to the lower contact feature 253, and the metal line portion 281b may be referred to as a dummy conductive feature. In some embodiments, the fourth voltage may be applied to the metal line portion 282b, and the lower contact feature 254 may be referred to as a dummy contact feature; or the fourth voltage may be applied to the lower contact feature 254, and the metal line portion 282b may be referred to as a dummy conductive feature.

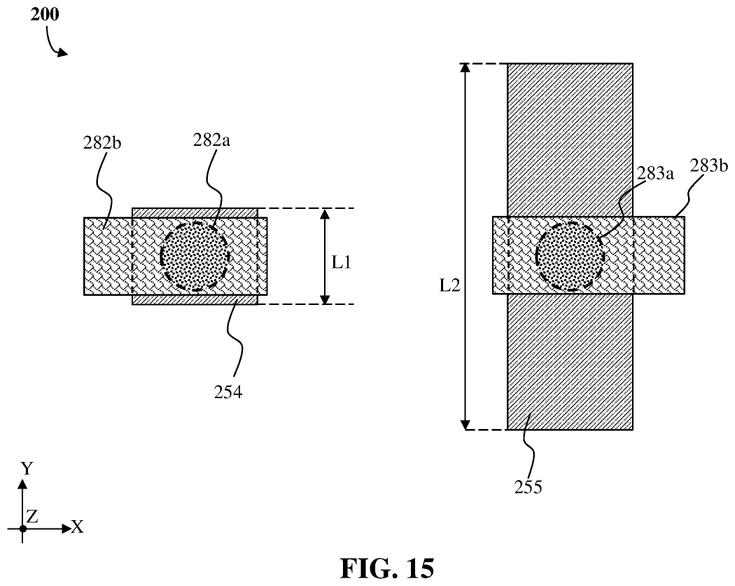

FIG. 15 depicts a fragmentary top view of the workpiece 200 shown in FIG. 14. Since the lower contact feature 254 may be a dummy contact feature, and the lower contact feature 255 may be a functional contact feature that may be electrically coupled to other conductive features, along the Y direction, a length L2 of the lower contact feature 255 is greater than a length L1 of the lower contact feature 254. For example, a ratio of the length L2 to the length L1 may be greater than 2. In some embodiments, a length L1 of the lower contact feature 254 may be substantially equal to a diameter of the contact via portion 282a to provide enough landing for the contact via portion 282a.

Referring to FIG. 1, method 100 includes a block 128 where further processes may be performed. Such further process may include formation of one or more passivation layers over the second dielectric layer 276, formation of the openings through the one or more passivation layers to expose the metal line portions 281b, 282b, and 283b, deposition of one or more polymeric material layers, patterning of the one or more polymeric material layers, deposition of an under-bump-metallurgy (or under-bump-metallization, UBM) layer, deposition of a copper-containing bump layer, deposition of a cap layer, deposition of a solder layer, and/or reflowing of the solder layer. These further processes form contact structures for connection to external circuitry.

In the above embodiments, the MIM capacitor 274 includes three conductor layers interleaved by two insulator layers. In some other implementations, the MIM capacitor may include more than three conductor layers to provide a higher capacitance. For example, FIG. 16 depicts a workpiece 200′ including a MIM capacitor 274′ that includes five conductor layers. More specifically, the MIM capacitor 274′ not only includes the first, second, and third conductor plate layers 262b, 266, 270 and the first and second insulator layers 264 and 268, but also includes a patterned third insulator layer 292 formed on the third conductor plate layer 270, a patterned fourth conductor layer 294 formed on the patterned third insulator layer 292, a patterned fourth insulator layer 296 formed on the patterned fourth conductor layer 294, and a patterned fifth conductor layer 298 formed on the patterned fourth insulator layer 296. By stacking more insulator layers and conductor layers, a total capacitance of the MIM capacitor may be increased. In the present embodiments, the upper contact feature 281 is further electrically coupled to patterned fourth conductor layer 294, and the upper contact feature 282 is further electrically coupled to patterned fifth conductor layer 298. In some other embodiments, one or more upper contact features may be formed to electrically couple to the patterned fourth conductor layer 294 or the patterned fifth conductor layer 298.

The present disclosure provides for many different embodiments. Semiconductor structures and methods of fabrication thereof are disclosed herein. In one exemplary aspect, the present disclosure is directed to a semiconductor structure. The semiconductor structure includes a first lower contact feature in a first dielectric layer, an etch stop layer on the first dielectric layer, a metal-insulator-metal (MIM) capacitor formed over the etch stop layer, wherein a bottom plate of the MIM capacitor is in direct contact with the etch stop layer, a second dielectric layer over the MIM capacitor, a first contact via extending through both the second dielectric layer and the MIM capacitor and electrically coupled to the first lower contact feature, and a first upper contact feature over and electrically coupled to the first contact via.

In some embodiments, the etch stop layer may include silicon carbide or aluminum nitride. In some embodiments, the first lower contact feature and the first upper contact feature may include copper (Cu). In some embodiments, the metal-insulator-metal (MIM) capacitor may include a bottom plate directly on the etch stop layer, a first insulator layer over the bottom plate, a middle plate over the first insulator layer, a second insulator layer over the middle plate, and a top plate over the second insulator layer. In some embodiments, the first upper contact feature may extend through the top plate, the second insulator layer, the first insulator layer, the bottom plate, and the etch stop layer. In some embodiments, the semiconductor structure may also include a second lower contact feature in the first dielectric layer and spaced apart from the first lower contact feature along a first direction, a conductive layer directly on the etch stop layer and spaced apart from the bottom plate along the first direction, a second contact via penetrating the middle plate and the conductive layer and electrically coupled to the second lower contact feature, and a second upper contact feature over and electrically coupled to the second contact via. In some embodiments, the conductive layer and the bottom plate may include the same composition and the same thickness. In some embodiments, the semiconductor structure may also include a third lower contact feature in the first dielectric layer and spaced apart from the first lower contact feature along a first direction, a third contact via extending through both the second dielectric layer and the etch stop layer, and electrically coupled to the third lower contact feature, a third upper contact feature over the third contact via and electrically coupled to the third contact via.

In another exemplary aspect, the present disclosure is directed to a semiconductor structure. The semiconductor structure includes a first metal line and a second metal line in a first dielectric layer, an etch stop layer disposed on the first dielectric layer and in direct contact with the first metal line and the second metal line, a first conductive layer disposed on the etch stop layer and directly over the first metal line, a second conductive layer disposed on the etch stop layer and directly over the second metal line, wherein a top surface of the second conductive layer is coplanar with a top surface of the first conductive layer, a third conductive layer disposed over the first conductive layer and vertically overlapped with both the first conductive layer and the second conductive layer, a fourth conductive layer disposed over the third conductive layer and vertically overlapped with the second conductive layer, a first conductive feature electrically coupled to the first metal line and extending through the third conductive layer, the first conductive layer, and the etch stop layer, and a second conductive feature electrically coupled to the second metal line and extending through the fourth conductive layer, the second conductive layer, and the etch stop layer.

In some embodiments, the semiconductor structure may include an insulator layer disposed vertically between the second conductive layer and the third conductive layer, and wherein the insulator layer comprises a high-k dielectric material. In some embodiments, a portion of the second conductive layer may be disposed directly over the second metal line and a portion of the second conductive layer may be disposed directly over the first dielectric layer. In some embodiments, the semiconductor structure may include a third metal line in the first dielectric layer and spaced apart from the second metal line along a first direction, a third conductive feature electrically coupled to the third metal line without penetrating the first conductive layer, the second conductive layer, the third conductive layer, and the fourth conductive layer. In some embodiments, the third metal line may extend lengthwise along a second direction perpendicular to the first direction and has a first length, and the first length may be greater than a length of the second metal line along the second direction. In some embodiments, the semiconductor structure may include a fifth conductive layer disposed over the fourth conductive layer, and a sixth conductive layer disposed over the fifth conductive layer. The first conductive feature may extend through the fifth conductive layer, and the second conductive feature may extend through the sixth conductive layer. In some embodiments, the etch stop layer may include silicon carbide or aluminum nitride.

In yet another exemplary aspect, the present disclosure is directed to a method. The method includes providing a workpiece that includes a first dielectric layer, a first lower contact feature, a second lower contact feature, and a third lower contact feature in the first dielectric layer. The method also includes depositing an etch stop layer directly on the first dielectric layer, forming a metal-insulator-metal capacitor over the etch stop layer, the metal-insulator-metal capacitor comprising a bottom plate directly on the etch stop layer, forming a second dielectric layer over the metal-insulator-metal capacitor, forming a first contact via penetrating multiple layers of the metal-insulator-metal capacitor to electrically couple to the first lower contact feature, and forming a second contact via penetrating multiple layers of the metal-insulator-metal capacitor to electrically couple to the second lower contact feature.

In some embodiments, the forming of the metal-insulator-metal capacitor may include depositing a first conductive layer directly on the etch stop layer, patterning the first conductive layer to form a conductive feature directly over the first lower contact feature and a bottom plate directly over the second lower contact feature, depositing a first insulator layer over the workpiece, forming a middle plate over the first insulator layer, the middle plate being vertically overlapped with the first lower contact feature, depositing a second insulator layer over the workpiece, and forming a top plate over the second insulator layer, the top plate being vertically overlapped with the second lower contact feature. In some embodiments, the forming of the first contact via and the second contact via may include performing a first etching process to form a first via opening extending through both the middle plate and the conductive feature and stop on the etch stop layer, and a second via opening extending through both the top plate and the bottom plate and stop on the etch stop layer, performing a second etching process to extend the first via opening and the second via opening, thereby exposing the first lower contact feature and the second lower contact feature, forming the first contact via in the extended first via opening, and forming the second contact via in the extended second via opening. In some embodiments, the workpiece may include a third lower contact feature formed in the first dielectric layer and spaced apart from the second lower contact feature along a first direction, the top plate is not vertically overlapped with the third lower contact feature. In some embodiments, the method may include, after the forming of the top plate, performing an etching process to remove portions of the second insulator layer and the first insulator layer directly over the third lower contact feature, and forming a third second contact via penetrating the second dielectric layer and in direct contact with the third lower contact feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first lower contact feature in a first dielectric layer;
an etch stop layer on the first dielectric layer;
a metal-insulator-metal (MIM) capacitor formed over the etch stop layer, wherein a bottom plate of the MIM capacitor is in direct contact with the etch stop layer;
a second dielectric layer over the MIM capacitor;
a first contact via extending through both the second dielectric layer and the MIM capacitor and electrically coupled to the first lower contact feature; and
a first upper contact feature over and electrically coupled to the first contact via.

2. The semiconductor structure of claim 1, wherein the etch stop layer comprises silicon carbide or aluminum nitride.

3. The semiconductor structure of claim 1, wherein the first lower contact feature and the first upper contact feature comprise copper (Cu).

4. The semiconductor structure of claim 1, wherein the metal-insulator-metal (MIM) capacitor comprises:
a bottom plate directly on the etch stop layer,
a first insulator layer over the bottom plate,
a middle plate over the first insulator layer,
a second insulator layer over the middle plate, and
a top plate over the second insulator layer.

5. The semiconductor structure of claim 4, wherein the first upper contact feature extends through the top plate, the second insulator layer, the first insulator layer, the bottom plate, and the etch stop layer.

6. The semiconductor structure of claim 4, further comprising:
a second lower contact feature in the first dielectric layer and spaced apart from the first lower contact feature along a first direction;
a conductive layer directly on the etch stop layer and spaced apart from the bottom plate along the first direction;
a second contact via penetrating the middle plate and the conductive layer and electrically coupled to the second lower contact feature; and
a second upper contact feature over and electrically coupled to the second contact via.

7. The semiconductor structure of claim 6, wherein the conductive layer and the bottom plate have the same composition and the same thickness.

8. The semiconductor structure of claim 4, further comprising:
a third lower contact feature in the first dielectric layer and spaced apart from the first lower contact feature along a first direction;
a third contact via extending through both the second dielectric layer and the etch stop layer, and electrically coupled to the third lower contact feature;
a third upper contact feature over the third contact via and electrically coupled to the third contact via.

9. A semiconductor structure, comprising:
a first metal line and a second metal line in a first dielectric layer;
an etch stop layer disposed on the first dielectric layer and in direct contact with the first metal line and the second metal line;
a first conductive layer disposed on the etch stop layer and directly over the first metal line;
a second conductive layer disposed on the etch stop layer and directly over the second metal line, wherein a top surface of the second conductive layer is coplanar with a top surface of the first conductive layer;
a third conductive layer disposed over the first conductive layer and vertically overlapped with both the first conductive layer and the second conductive layer;
a fourth conductive layer disposed over the third conductive layer and vertically overlapped with the second conductive layer;
a first conductive feature electrically coupled to the first metal line and extending through the third conductive layer, the first conductive layer, and the etch stop layer; and
a second conductive feature electrically coupled to the second metal line and extending through the fourth conductive layer, the second conductive layer, and the etch stop layer.

10. The semiconductor structure of claim 9, further comprising: an insulator layer disposed vertically between the second conductive layer and the third conductive layer, and wherein the insulator layer comprises a high-k dielectric material.

11. The semiconductor structure of claim 9, wherein a portion of the second conductive layer is disposed directly over the second metal line and a portion of the second conductive layer is disposed directly over the first dielectric layer.

12. The semiconductor structure of claim 9, further comprising:
a third metal line in the first dielectric layer and spaced apart from the second metal line along a first direction;
a third conductive feature electrically coupled to the third metal line without penetrating the first conductive layer, the second conductive layer, the third conductive layer, and the fourth conductive layer.

13. The semiconductor structure of claim 12, wherein the third metal line extends lengthwise along a second direction perpendicular to the first direction and has a first length, wherein the first length is greater than a length of the second metal line along the second direction.

14. The semiconductor structure of claim 9, further comprising:
a fifth conductive layer disposed over the fourth conductive layer; and
a sixth conductive layer disposed over the fifth conductive layer,
wherein the first conductive feature further extends through the fifth conductive layer, and wherein the second conductive feature further extends through the sixth conductive layer.

15. The semiconductor structure of claim 9, wherein the etch stop layer comprises silicon carbide or aluminum nitride.

16. A method, comprising:
providing a workpiece comprising:
a first dielectric layer; and
a first lower contact feature, a second lower contact feature, and a third lower contact feature in the first dielectric layer;
depositing an etch stop layer directly on the first dielectric layer;
forming a metal-insulator-metal capacitor over the etch stop layer, the metal-insulator-metal capacitor comprising a bottom plate directly on the etch stop layer;
forming a second dielectric layer over the metal-insulator-metal capacitor;
forming a first contact via penetrating multiple layers of the metal-insulator-metal capacitor to electrically couple to the first lower contact feature; and
forming a second contact via penetrating multiple layers of the metal-insulator-metal capacitor to electrically couple to the second lower contact feature.

17. The method of claim 16, wherein the forming of the metal-insulator-metal capacitor comprises:
depositing a first conductive layer directly on the etch stop layer;
patterning the first conductive layer to form a conductive feature directly over the first lower contact feature and a bottom plate directly over the second lower contact feature;
depositing a first insulator layer over the workpiece;
forming a middle plate over the first insulator layer, the middle plate being vertically overlapped with the first lower contact feature;
depositing a second insulator layer over the workpiece; and
forming a top plate over the second insulator layer, the top plate being vertically overlapped with the second lower contact feature.

18. The method of claim 17, wherein the forming of the first contact via and the second contact via comprises:
performing a first etching process to form a first via opening extending through both the middle plate and the conductive feature and stop on the etch stop layer, and a second via opening extending through both the top plate and the bottom plate and stop on the etch stop layer;
performing a second etching process to extend the first via opening and the second via opening, thereby exposing the first lower contact feature and the second lower contact feature;
forming the first contact via in the extended first via opening; and
forming the second contact via in the extended second via opening.

19. The method of claim 18, wherein the workpiece further comprises a third lower contact feature formed in the first dielectric layer and spaced apart from the second lower contact feature along a first direction, wherein the top plate is not vertically overlapped with the third lower contact feature.

20. The method of claim 19, further comprising:
after the forming of the top plate, performing an etching process to remove portions of the second insulator layer and the first insulator layer directly over the third lower contact feature; and
forming a third second contact via penetrating the second dielectric layer and in direct contact with the third lower contact feature.
